(19) United States
(12) Patent Application Publication
(10) Pub. No.: US 2019/0103540 A1
(43) Pub. Date: Apr. 4, 2019

(54) DOUBLE-SIDED METAL CLAD LAMINATE BASED FLEXIBLE THERMOELECTRIC DEVICE AND MODULE

(71) Applicant: Sridhar Kasichainula, Fremont, CA (US)

(72) Inventor: Sridhar Kasichainula, Fremont, CA (US)

(21) Appl. No.: 16/207,076

(22) Filed: Nov. 30, 2018

Related U.S. Application Data
(63) Continuation-in-part of application No. 15/808,902, filed on Nov. 10, 2017.
Application No. 15/808,902 is a continuation-in-part of application No. 14/564,072, filed on Dec. 8, 2014.
Application No. 15/808,902 is a continuation-in-part of application No. 14/711,810, filed on May 14, 2015, now Pat. No. 10,141,492.
Application No. 14/711,810 is a continuation-in-part of application No. 15/368,683, filed on Dec. 5, 2016.
(60) Provisional application No. 61/912,561, filed on Dec. 6, 2013.

(51) Int. Cl. H01L 35/34; H01L 35/32

(52) U.S. Cl. CPC H01L 35/34; H01L 35/32

(57) ABSTRACT

A method includes sputter depositing pairs of N-type thermoelectric legs and P-type thermoelectric legs electrically in contact with one another on both metal clad surfaces of a double-sided metal clad laminate, and forming a thin-film based thermoelectric module with the sputter deposited pairs of the N-type thermoelectric legs and the P-type thermoelectric legs on each of the metal clad surfaces. The method also includes rendering the formed thin-film based thermoelectric module flexible based on choices of fabrication processes with respect to layers of the formed thin-film based thermoelectric module, and improving performance of a thermoelectric device including the formed thin-film based thermoelectric module on the each of the metal clad surfaces based on efficiently utilizing a temperature difference between both the metal clad surfaces.

### CLAIM OF PRIORITY

This application is a Continuation-in-Part application of co-pending U.S. application Ser. No. 15/808,902 titled FLEXIBLE THIN-FILM BASED THERMOELECTRIC DEVICE WITH SPUTTER DEPOSITED LAYER OF N-TYPE AND P-TYPE THERMOELECTRIC LEGS filed on Nov. 10, 2017, which is a Continuation-in-Part application of co-pending U.S. patent application Ser. No. 14/564,072 titled VOLTAGE GENERATION ACROSS TEMPERATURE DIFFERENTIALS THROUGH A THERMOELECTRIC LAYER COMPOSITE filed on Dec. 8, 2014, which is a conversion application of U.S. Provisional Application No. 61/912,561 also titled VOLTAGE GENERATION ACROSS TEMPERATURE DIFFERENTIALS THROUGH A THERMOELECTRIC LAYER COMPOSITE filed on Dec. 6, 2013, U.S. application Ser. No. 14/711,810 titled ENERGY HARVESTING FOR WEARABLE TECHNOLOGY THROUGH A THIN FLEXIBLE THERMOELECTRIC DEVICE filed on May 14, 2015 and issued as U.S. Pat. No. 10,141,492 on Nov. 27, 2018 and co-pending U.S. application Ser. No. 15/368,683 titled PIN COUPLING BASED THERMOELECTRIC DEVICE filed on Dec. 5, 2016. The content of the aforementioned applications are incorporated by reference in entirety thereof.

### FIELD OF TECHNOLOGY

This disclosure relates generally to thermoelectric devices and, more particularly, to a double sided metal clad laminate based flexible thermoelectric device and module.

### BACKGROUND

A thermoelectric device may be formed from alternating N and P elements/legs made of semiconducting material on a rigid substrate (e.g., alumina) joined on a top thereof to another rigid substrate/plate (e.g., again, alumina). However, a traditional implementation of the thermoelectric device may not utilize a temperature difference between a top portion and a bottom portion of the rigid substrate efficiently, thereby leading to decreased performance thereof.

### SUMMARY

Disclosed are methods, a device and/or a system of a double sided metal clad laminate based flexible thermoelectric device and module.

In one aspect, a method includes sputter depositing pairs of N-type thermoelectric legs and P-type thermoelectric legs electrically in contact with one another on both metal clad surfaces of a double-sided metal clad laminate, and forming a thin-film based thermoelectric module with the sputter deposited pairs of the N-type thermoelectric legs and the P-type thermoelectric legs on each of the metal clad surfaces. The double-sided metal clad laminate serves as a flexible substrate.

The method also includes rendering the formed thin-film based thermoelectric module flexible based on choices of fabrication processes with respect to layers of the formed thin-film based thermoelectric module including the sputter deposited N-type thermoelectric legs and the P-type thermoelectric legs. The flexibility enables an array of thin-film based thermoelectric modules, each of which is equivalent to the thin-film based thermoelectric module formed on the each of the metal clad surfaces, to be completely wrappable and bendable around a system element from which the array of the thin-film based thermoelectric modules is configured to derive thermoelectric power.

Further, the method includes improving performance of a thermoelectric device including the formed thin-film based thermoelectric module on the each of the metal clad surfaces of the double-sided metal clad laminate based on the formed thin-film based thermoelectric module on the each of the metal clad surfaces utilizing a temperature difference between both the metal clad surfaces compared to the thermoelectric device including the formed thin-film based thermoelectric module on only one metal clad surface of the double-sided metal clad laminate.

In another aspect, a method includes sputter depositing pairs of N-type thermoelectric legs and P-type thermoelectric legs electrically in contact with one another on both metal clad surfaces of a double-sided metal clad laminate, and forming a thin-film based thermoelectric module with the sputter deposited pairs of the N-type thermoelectric legs and the P-type thermoelectric legs on each of the metal clad surfaces. The double-sided metal clad laminate serves as a flexible substrate.

The method also includes rendering the formed thin-film based thermoelectric module flexible based on choices of fabrication processes with respect to layers of the formed thin-film based thermoelectric module including the sputter deposited N-type thermoelectric legs and the P-type thermoelectric legs, and wrapping and bending an array of thin-film based thermoelectric modules, each of which is equivalent to the thin-film based thermoelectric module formed on the each of the metal clad surfaces, completely around a system element from which the array of the thin-film based thermoelectric modules is configured to derive thermoelectric power in accordance with the flexibility thereof.

Further, the method includes improving performance of a thermoelectric device including the formed thin-film based thermoelectric module on the each of the metal clad surfaces of the double-sided metal clad laminate based on the formed thin-film based thermoelectric module on the each of the metal clad surfaces utilizing a temperature difference between both the metal clad surfaces compared to the thermoelectric device including the formed thin-film based thermoelectric module on only one metal clad surface of the double-sided metal clad laminate.

In yet another aspect, a method includes sputter depositing pairs of N-type thermoelectric legs and P-type thermoelectric legs electrically in contact with one another on both metal clad surfaces of a double-sided metal clad laminate, and forming a thin-film based thermoelectric device out of an array of thermoelectric modules, each of which is formed with the sputter deposited pairs of the N-type thermoelectric legs and the P-type thermoelectric legs on each of the metal clad surfaces. The double-sided metal clad laminate serves as a flexible substrate.

The method also includes rendering the formed thin-film based thermoelectric device flexible based on choices of fabrication processes with respect to layers of the each thermoelectric module including the sputter deposited N-type thermoelectric legs and the P-type thermoelectric legs. The flexibility enables the formed thin-film based thermoelectric device to be completely wrappable and bendable around a system element from which the formed thin-film based thermoelectric device is configured to derive thermoelectric power.

Further, the method includes improving performance of the formed thin-film based thermoelectric device based on the each thermoelectric module of the array of thermoelectric modules with the sputter deposited pairs of the N-type thermoelectric legs and the P-type thermoelectric legs on the each of the metal clad surfaces utilizing a temperature difference between both the metal clad surfaces compared to the each thermoelectric module with the sputter deposited pairs of the N-type thermoelectric legs and the P-type thermoelectric legs on only one metal clad surface of the double-sided metal clad laminate thereof.

Other features will be apparent from the accompanying drawings and from the detailed description that follows.

### BRIEF DESCRIPTION OF THE DRAWINGS

The embodiments of this invention are illustrated by way of example and not limitation in the figures of the accompanying drawings, in which like references indicate similar elements and in which:

FIG. 1 is a schematic view of a thermoelectric device.

FIG. 2 is a schematic view of an example thermoelectric device with alternating P and N elements.

FIG. 3 is a top schematic view of a thermoelectric device component, according to one or more embodiments.

FIG. 4 is a process flow diagram detailing the operations involved in realizing a patterned flexible substrate of a thermoelectric device as per a design pattern, according to one or more embodiments.

FIG. 5 is a schematic view of the patterned flexible substrate of FIG. 4, according to one or more embodiments.

FIG. 6 is a schematic view of the patterned flexible substrate of FIG. 4 with N-type thermoelectric legs, P-type thermoelectric legs, a barrier layer and conductive interconnects, according to one or more embodiments.

FIG. 7 is a process flow diagram detailing the operations involved in sputter deposition of the N-type thermoelectric legs of FIG. 6 on the patterned flexible substrate (or, a seed metal layer) of FIG. 5, according to one or more embodiments.

FIG. 8 is a process flow diagram detailing the operations involved in deposition of the barrier layer of FIG. 6 on top of the sputter deposited pairs of P-type thermoelectric legs and the N-type thermoelectric legs of FIG. 6 and forming the conductive interconnects of FIG. 6 on top of the barrier layer, according to one or more embodiments.

FIG. 9 is a process flow diagram detailing the operations involved in encapsulating the thermoelectric device of FIG. 4 and FIG. 6, according to one or more embodiments.

FIG. 10 is a schematic view of a flexible thermoelectric device embedded within a watch strap of a watch completely wrappable around a wrist of a human being.

FIG. 11 is a schematic view of a flexible thermoelectric device wrapped around a heat pipe.

FIG. 12 is a schematic view of a double-sided metal clad laminate sheet roll, according to one or more embodiments.

FIG. 13 is a schematic view of another patterned flexible substrate analogous to the patterned flexible substrate of FIGS. 4-5, according to one or more embodiments.

FIG. 14 is a process flow diagram detailing the operations involved in improving performance of a thermoelectric device, according to one or more embodiments.

Other features of the present embodiments will be apparent from the accompanying drawings and from the detailed description that follows.

### DETAILED DESCRIPTION

Example embodiments, as described below, may be used to provide methods, a device and/or a system of a double sided metal clad laminate based flexible thermoelectric device and module. Although the present embodiments have been described with reference to specific example embodiments, it will be evident that various modifications and changes may be made to these embodiments without departing from the broader spirit and scope of the various embodiments.

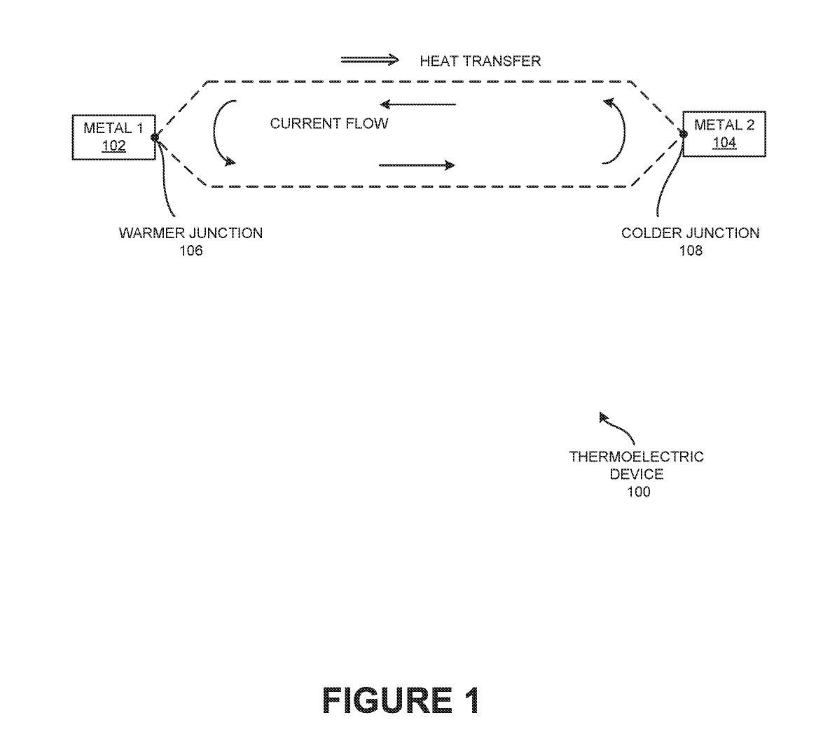

FIG. 1 shows a thermoelectric device 100. Thermoelectric device 100 may include different metals, metal 1 102 and metal 2 104, forming a closed circuit. Here, a temperature difference between junctions of said dissimilar metals leads to energy levels of electrons therein shifted in a dissimilar manner. This results in a potential/voltage difference between the warmer (e.g., warmer junction 106) of the junctions and the colder (e.g., colder junction 108) of the junctions. The aforementioned conversion of heat into electricity at junctions of dissimilar metals is known as Seebeck effect.

The most common thermoelectric devices in the market may utilize alternative P and N type legs/pellets/elements made of semiconducting materials. As heat is applied to one end of a thermoelectric device based on P and N type elements, charge carriers thereof may be released into the conduction band. Electron (charge carrier) flow in the N type element may contribute to a current flowing from the end (hot end) where the heat is applied to the other end (cold end). Hole (charge carrier) flow in the P type element may contribute to a current flowing from the other end (cold end) to the end (hot end) where the heat is applied. Here, heat may be removed from the cold end to prevent equalization of charge carrier distribution in the semiconductor materials due to migration thereof.

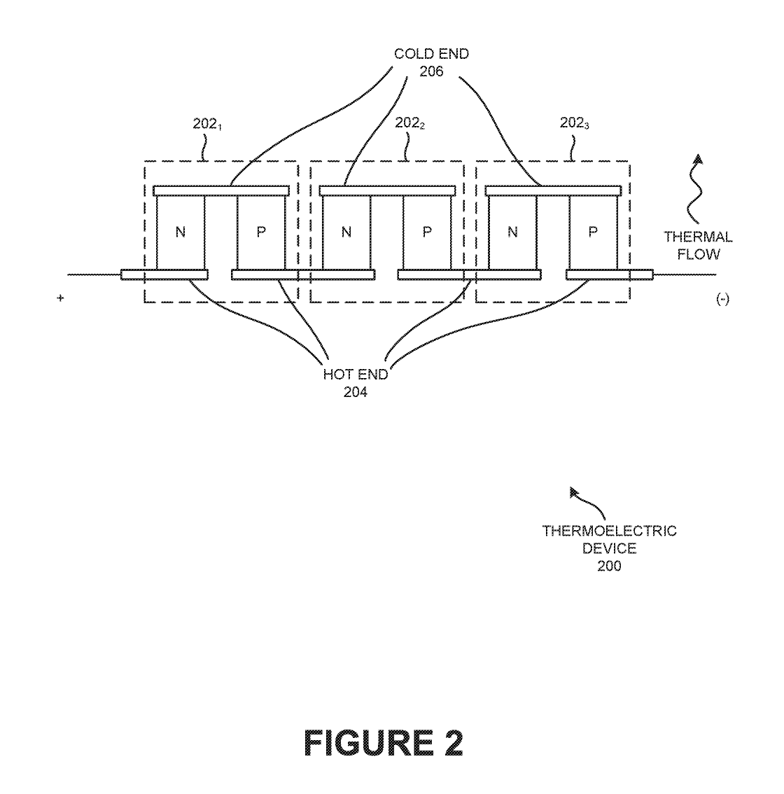

In order to generate voltage at a meaningful level to facilitate one or more application(s), typical thermoelectric devices may utilize alternating P and N type elements (legs/pellets) electrically coupled in series (and thermally coupled in parallel) with one another, as shown in FIG. 2. FIG. 2 shows an example thermoelectric device 200 including three alternating P and N type elements 202₁₋₃. The hot end (e.g., hot end 204) where heat is applied and the cold end (e.g., cold end 206) are also shown in FIG. 2.

Typical thermoelectric devices (e.g., thermoelectric device 200) may be limited in application thereof because of rigidity, bulkiness and high costs (>$20/watt) associated therewith. Also, these devices may operate at high temperatures using active cooling. Exemplary embodiments discussed herein provide for a thermoelectric platform (e.g., enabled via roll-to-roll sputtering on a flexible substrate (e.g., plastic)) that offers a large scale, commercially viable, high performance, easy integration and inexpensive (<20 cents/watt) route to flexible thermoelectrics.

In accordance with the exemplary embodiments, P and N thermoelectric legs may be deposited on a flexible substrate (e.g., plastic) using a roll-to-roll process that offers scalability and cost savings associated with the N and P materials. In a typical solution, bulk legs may have a height in millimeters (mm) and an area in mm². In contrast, N and P bulk legs described in the exemplary embodiments discussed herein may have a height in microns (μm) and an area in the μm² to mm² range.

Examples of flexible substrates may include but are not limited to aluminum (Al) foil, a sheet of paper, teflon, plastic and a single/double-sided copper (Cu) clad laminate sheet. As will be discussed below, exemplary embodiments involve processes for manufacturing/fabrication of thermoelectric devices/modules that enable flexibility thereof not only in terms of substrates but also in terms of thin films/thermoelectric legs/interconnects/packaging. Preferably, exemplary embodiments provide for thermoelectric devices/modules completely wrappable and bendable around other devices utilized in specific applications, as will be discussed below. Further, exemplary embodiments provide for manufactured/fabricated thermoelectric devices/modules that are each less than or equal to 100 μm in dimensional thickness.

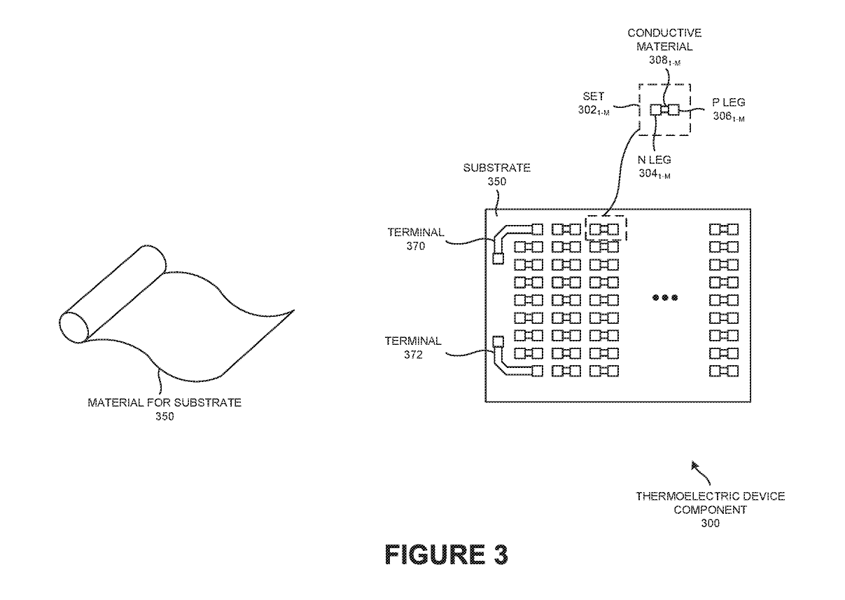

FIG. 3 shows a top view of a thermoelectric device component 300, according to one or more embodiments. Here, in one or more embodiments, a number of sets of N and P legs (e.g., sets 302_{1-M} including N legs 304_{1-M} and P legs 306_{1-M} therein) may be deposited on a substrate 350 (e.g., plastic, Cu clad laminate sheet) using a roll-to-roll process discussed above. FIG. 3 also shows a conductive material 308_{1-M} contacting both a set 302_{1-M} and substrate 350, according to one or more embodiments; an N leg 304_{1-M} and a P leg 306_{1-M} form a set 302_{1-M}, in which N leg 304_{1-M} and P leg 306_{1-M} electrically contact each other through conductive material 308_{1-M}. Terminals 370 and 372 may be electrically conductive leads to measure the potential difference generated by a thermoelectric device including thermoelectric device component 300. Exemplary thermoelectric devices discussed herein may find utility in solar and solar thermal applications. As discussed above, traditional thermoelectric devices may have a size limitation and may not scale to a larger area. For example, a typical solar panel may have an area in the square meter (m²) range and the traditional thermoelectric device may have an area in the square inch range. A thermoelectric device in accordance with the exemplary embodiments may be of varying sizes and/or dimensions ranging from a few mm² to a few m².

Additionally, exemplary thermoelectric devices may find use in low temperature applications such as harvesting body heat in a wearable device, automotive devices/components and Internet of Things (IoT). Entities (e.g., companies, start-ups, individuals, conglomerates) may possess expertise to design and/or develop devices that require thermoelectric modules, but may not possess expertise in the fabrication and packaging of said thermoelectric modules. Alternately, even though the entities may possess the requisite expertise in the fabrication and packaging of the thermoelectric modules, the entities may not possess a comparative advantage with respect to the aforementioned processes.

In one scenario, an entity may create or possess a design pattern for a thermoelectric device. Said design pattern may be communicated to another entity associated with a thermoelectric platform to be tangibly realized as a thermoelectric device. It could also be envisioned that the another entity may provide training with regard to the fabrication processes to the one entity or outsource aspects of the fabrication processes to a third-party. Further, the entire set of processes involving Intellectual Property (IP) generation and manufacturing/fabrication of the thermoelectric device may be handled by a single entity. Last but not the least, the entity may generate the IP involving manufacturing/fabrication of the thermoelectric device and outsource the actual manufacturing/fabrication processes to the another entity.

All possible combinations of entities and third-parties are within the scope of the exemplary embodiments discussed herein.

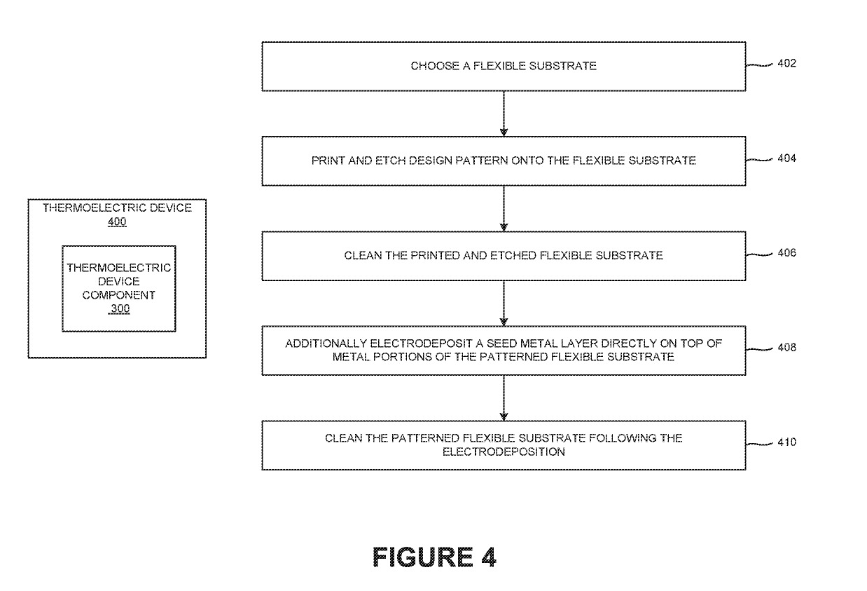

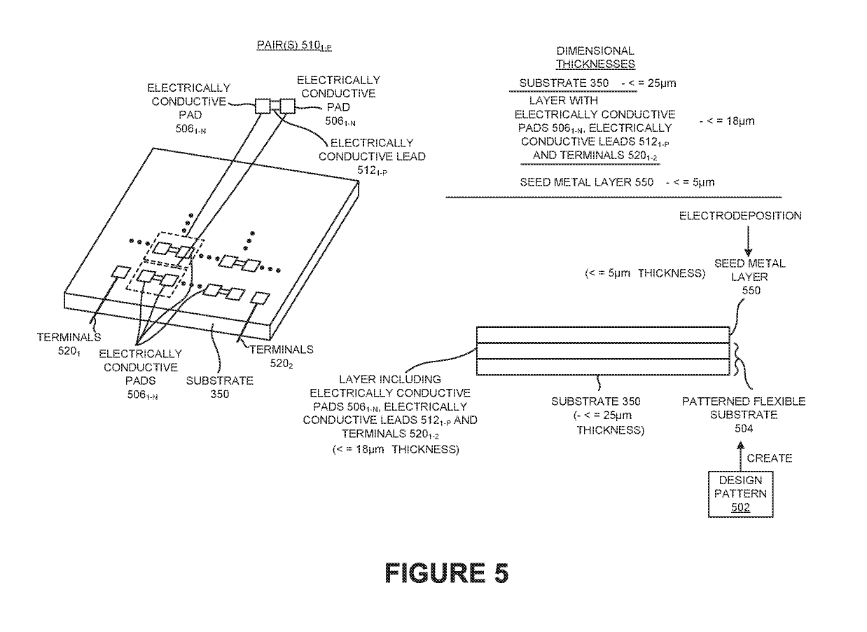

FIG. 4 shows the operations involved in realizing a patterned flexible substrate (e.g., patterned flexible substrate 504 shown in FIG. 5) of a thermoelectric device 400 as per a design pattern (e.g., design pattern 502 shown in FIG. 5), according to one or more embodiments. In one or more embodiments, operation 402 may involve choosing a flexible substrate (e.g., substrate 350) onto which, in operation 404, design pattern 502 may be printed (e.g., through inkjet printing, direct write, screen printing) and etched onto the flexible substrate. In one or more embodiments, a dimensional thickness of substrate 350 may be less than or equal to 25 μm.

Etching, as defined above, may refer to the process of removing (e.g., chemically) unwanted metal (say, Cu) from the patterned flexible substrate. In one example embodiment, a mask or a resist may be placed on portions of the patterned flexible substrate corresponding to portions of the metal that are to remain after the etch. Here, in one or more embodiments, the portions of the metal that remain on the patterned flexible substrate may be electrically conductive pads, electrically conductive leads and terminals formed on a surface of the patterned flexible substrate. FIG. 5 shows a patterned flexible substrate 504 including a number of electrically conductive pads 506_{1-N} formed thereon. Each electrically conductive pad 506_{1-N} may be a flat area of the metal that enables an electrical connection.

Also, FIG. 5 shows a majority set of the electrically conductive pads 506_{1-N} as including pairs 510_{1-P} of electrically conductive pads 506_{1-N} in which one electrically conductive pad 506_{1-N} may be electrically paired to another electrically conductive pad 506_{1-N} through an electrically conductive lead 512_{1-P} also formed on patterned flexible substrate 504; terminals 520₁₋₂ (e.g., analogous to terminals 370 and 372) may also be electrically conductive leads to measure the potential difference generated by the thermoelectric device/module fabricated based on design pattern 502. The aforementioned potential difference may be generated based on heat (or, cold) applied at an end of the thermoelectric device/module.

It should be noted that the configurations of the electrically conductive pads 506_{1-N}, electrically conductive leads 512_{1-P} and terminals 520₁₋₂ shown in FIG. 5 are merely for example purposes, and that other example configurations are within the scope of the exemplary embodiments discussed herein. It should also be noted that patterned flexible substrate 504 may be formed based on design pattern 502 in accordance with the printing and etching discussed above.

Example etching solutions employed may include but are not limited to ferric chloride and ammonium persulphate. Referring back to FIG. 4, operation 406 may involve cleaning the printed and etched flexible substrate. For example, acetone, hydrogen peroxide or alcohol may be employed therefor. Other forms of cleaning are within the scope of the exemplary embodiments discussed herein. In one or more embodiments, the aforementioned processes discussed in FIG. 4 may result in a dimensional thickness of electrically conductive pads 506_{1-N}, electrically conductive leads 512_{1-P} and terminals 520₁₋₂ being less than or equal to 18 μm.

The metal (e.g., Cu) finishes on the surface of patterned flexible substrate 504 may oxidize over time if left unprotected. As a result, in one or embodiments, operation 408 may involve additionally electrodepositing a seed metal layer 550 including Chromium (Cr), Nickel (Ni) and/or Gold (Au) directly on top of the metal portions (e.g., electrically conductive pads 506_{1-N}, electrically conductive leads 512_{1-P}, terminals 520₁₋₂) of patterned flexible substrate 504 following the printing, etching and cleaning. In one or more embodiments, a dimensional thickness of seed metal layer 550 may be less than or equal to 5 μm.

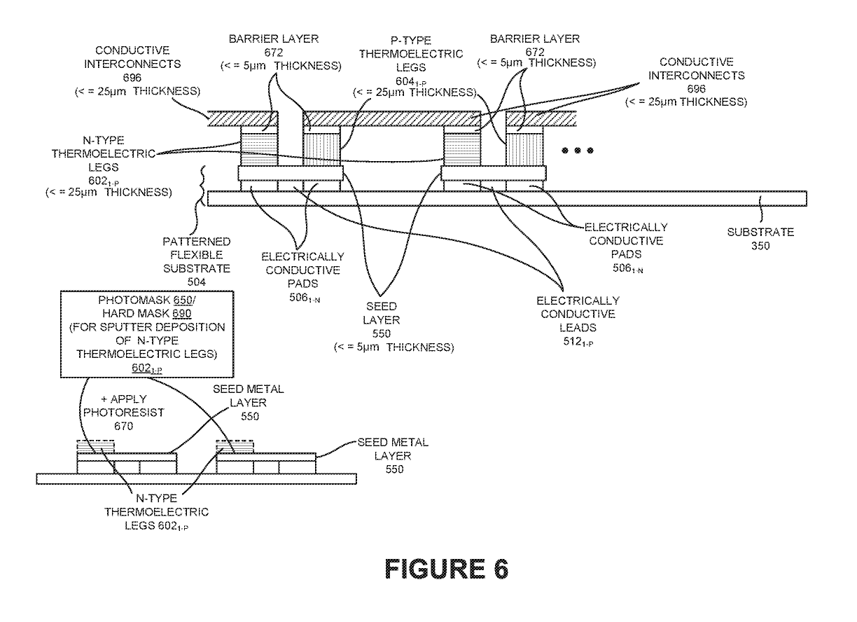

In one example embodiment, surface finishing may be employed to electrodeposit seed metal layer 550; the aforementioned surface finishing may involve Electroless Nickel Immersion Gold (ENIG) finishing. Here, a coating of two layers of metal may be provided over the metal (e.g., Cu) portions of patterned flexible substrate 504 by way of Au being plated over Ni. Ni may be the barrier layer between Cu and Au. Au may protect Ni from oxidization and may provide for low contact resistance. Other forms of surface finishing/electrodeposition may be within the scope of the exemplary embodiments discussed herein. It should be noted that seed metal layer 550 may facilitate contact of sputter deposited N-type thermoelectric legs (to be discussed below) and P-type thermoelectric legs (to be discussed below) thereto. In one or more embodiments, operation 410 may then involve cleaning patterned flexible substrate 504 following the electrodeposition. FIG. 6 shows an N-type thermoelectric leg 602_{1-P} and a P-type thermoelectric leg 604_{1-P} formed on each pair 510_{1-P} of electrically conductive pads 506_{1-N}, according to one or more embodiments. In one or more embodiments, the aforementioned N-type thermoelectric legs 602_{1-P} and P-type thermoelectric legs 604_{1-P} may be formed on the surface finished patterned flexible substrate 504 (note: in FIG. 6, seed layer 550 is shown as surface finishing over electrically conductive pads 506_{1-N}/leads 512_{1-P}; terminals 520₁₋₂ have been omitted for the sake of clarity) of FIG. 5 through sputter deposition.

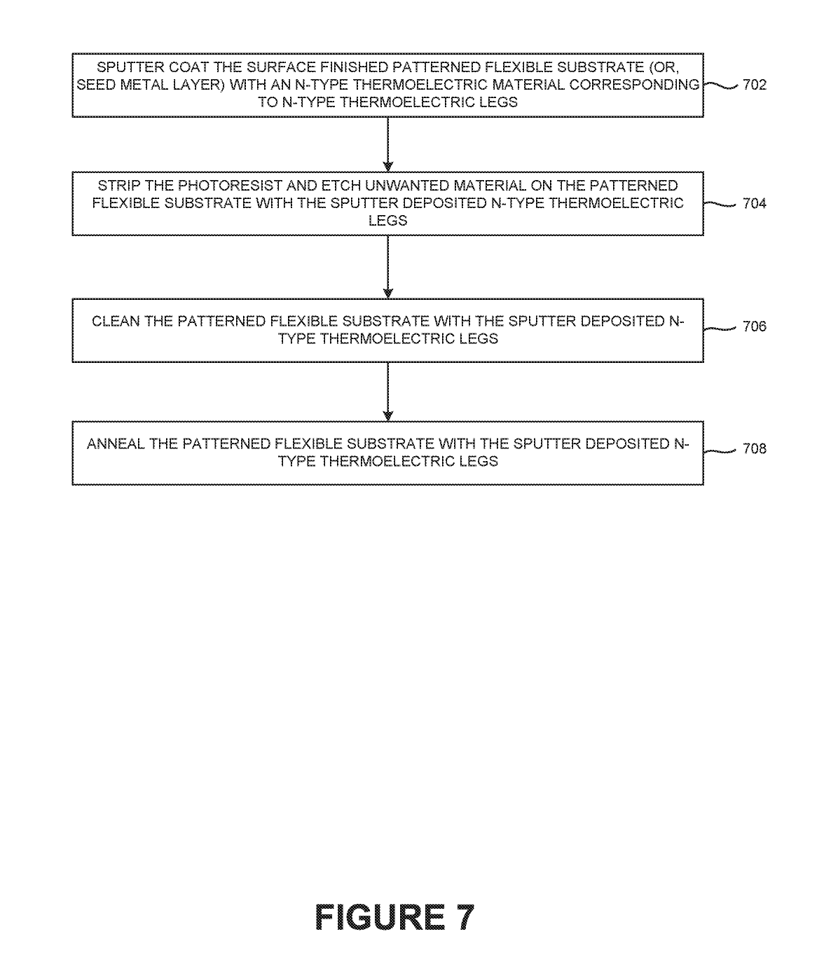

FIG. 7 details the operations involved in sputter deposition of N-type thermoelectric legs 602_{1-P} on the surface finished patterned flexible substrate 504 (or, seed metal layer 550) of FIG. 5, according to one or more embodiments. In one or more embodiments, the aforementioned process may involve a photomask 650 (shown in FIG. 6) on which patterns corresponding/complementary to the N-type thermoelectric legs 602_{1-P} may be generated. In one or more embodiments, a photoresist 670 (shown in FIG. 6) may be applied on the surface finished patterned flexible substrate 504, and photomask 650 placed thereon. In one or more embodiments, operation 702 may involve sputter coating (e.g., through magnetron sputtering) of the surface finished patterned flexible substrate 504 (or, seed metal layer 550) with an N-type thermoelectric material corresponding to N-type thermoelectric legs 602_{1-P}, aided by the use of photomask 650. The photoresist 670/photomask 650 functions are well understood to one skilled in the art; detailed discussion associated therewith has been skipped for the sake of convenience and brevity.

In one or more embodiments, operation 704 may involve stripping (e.g., using solvents such as dimethyl sulfoxide or alkaline solutions) of photoresist 670 and etching of unwanted material on patterned flexible substrate 504 with sputter deposited N-type thermoelectric legs 602_{1-P}. In one or more embodiments, operation 706 may involve cleaning the patterned flexible substrate 504 with the sputter deposited N-type thermoelectric legs 602_{1-P}; the cleaning process may be similar to the discussion with regard to FIG. 4.

In one or more embodiments, operation 708 may then involve annealing the patterned flexible substrate 504 with the sputter deposited N-type thermoelectric legs 602_{1-P}; the annealing process may be conducted (e.g., in air or vacuum) at 175° C. for 4 hours. In one or more embodiments, the annealing process may remove internal stresses and may contribute stability of the sputter deposited N-type thermoelectric legs 602_{1-P}. In one or more embodiments, a dimensional thickness of the sputter deposited N-type thermoelectric legs 602_{1-P} may be less than or equal to 25 μm.

It should be noted that P-type thermoelectric legs 604_{1-P} may also be sputter deposited on the surface finished pattern flexible substrate 504. The operations associated therewith are analogous to those related to the sputter deposition of N-type thermoelectric legs 602_{1-P}. Obviously, photomask 650 may have patterns corresponding/complementary to the P-type thermoelectric legs 604_{1-P} generated thereon. Detailed discussion associated with the sputter deposition of P-type thermoelectric legs 604_{1-P} has been skipped for the sake of convenience; it should be noted that a dimensional thickness of the sputter deposited P-type thermoelectric legs 604_{1-P} may also be less than or equal to 25 μm.

It should be noted that the sputter deposition of P-type thermoelectric legs 604_{1-P} on the surface finished patterned flexible substrate 504 may be performed after the sputter deposition of N-type thermoelectric legs 602_{1-P} thereon or vice versa. Also, it should be noted that various feasible forms of sputter deposition are within the scope of the exemplary embodiments discussed herein. In one or more embodiments, the sputter deposited P-type thermoelectric legs 604_{1-P} and/or N-type thermoelectric legs 602_{1-P} may include a material chosen from one of: Bismuth Telluride (Bi₂Te₃), Bismuth Selenide (Bi₂Se₃), Antimony Telluride (Sb₂Te₃), Lead Telluride (PbTe), Silicides, Skutterudites and Oxides.

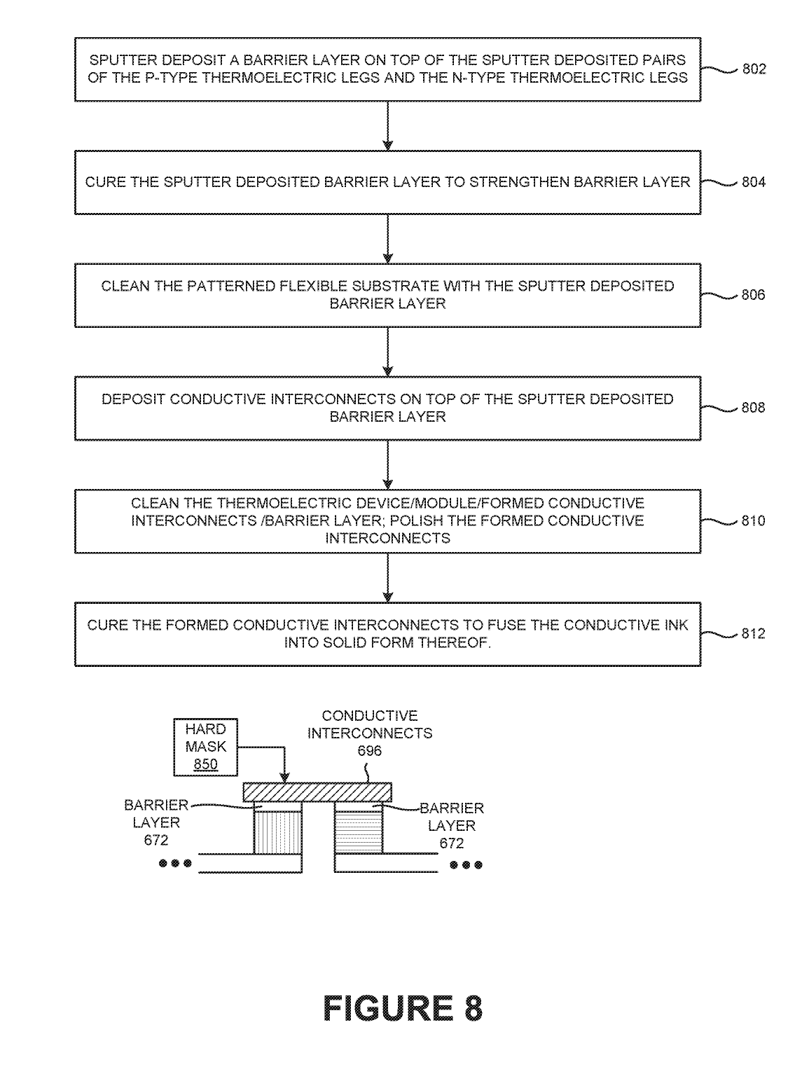

FIG. 8 details operations involved in deposition of a barrier layer 672 (refer to FIG. 6) on top of the sputter deposited pairs of P-type thermoelectric legs 604_{1-P} and N-type thermoelectric legs 602_{1-P} and forming conductive interconnects 696 on top of barrier layer 672, according to one or more embodiments.

In one or more embodiments, operation 802 may involve sputter depositing barrier layer 672 (e.g., film) on top of the sputter deposited pairs of the P-type thermoelectric legs 604_{1-P} and the N-type thermoelectric leg 602_{1-P} discussed above. In one or more embodiments, barrier layer 672 may be electrically conductive and may have a higher melting temperature than the thermoelectric material forming the P-type thermoelectric legs 604_{1-P} and the N-type thermoelectric legs 602_{1-P}. In one or more embodiments, barrier layer 672 may prevent corruption (e.g., through diffusion, sublimation) of one layer (e.g., the thermoelectric layer including the P-type thermoelectric legs 604_{1-P} and the N-type thermoelectric legs 602_{1-P}) by another layer. An example material employed as barrier layer 672 may include but is not limited to Cr, Ni or Au. Further, in one or more embodiments, barrier layer 672 may further aid metallization contact therewith (e.g., with conductive interconnects 696).

In one or more embodiments, a dimensional thickness of barrier layer 672 may be less than or equal to 5 μm. It is obvious that another photomask (not shown) analogous to photomask 650 may be employed to aid the patterned sputter deposition of barrier layer 672; details thereof have been skipped for the sake of convenience and clarity. In one or more embodiments, operation 804 may involve may involve curing barrier layer 672 at 175° C. for 4 hours to strengthen barrier layer 672. In one or more embodiments, operation 806 may then involve cleaning patterned flexible substrate 504 with barrier layer 672.

In one or more embodiments, operation 808 may involve depositing conductive interconnects 696 on top of barrier layer 672. In one example embodiment, the aforementioned deposition may be accomplished by screen printing silver (Ag) ink or other conductive forms of ink on barrier layer 672. Other forms of conductive interconnects 696 based on conductive paste(s) are within the scope of the exemplary embodiments discussed herein. As shown in FIG. 8, a hard mask 850 may be employed to assist the selective application of conductive interconnects 696 based on screen printing of Ag ink. In one example embodiment, hard mask 850 may be a stencil. In one or more embodiments, the screen printing of Ag ink may contribute to the continued flexibility of the thermoelectric device/module and low contact resistance. In one or more embodiments, operation 810 may involve cleaning (e.g., using one or more of the processes discussed above) the thermoelectric device/module/formed conductive interconnects 696/barrier layer 672 and polishing conductive interconnects 696. In one example embodiment, the polishing may be followed by another cleaning process. In one or more embodiments, operation 812 may then involve curing conductive interconnects 696 at 175° C. for 4 hours to fuse the conductive ink into solid form thereof. In one or more embodiments, conductive interconnects 696 may have a dimensional thickness less than or equal to 25 μm.

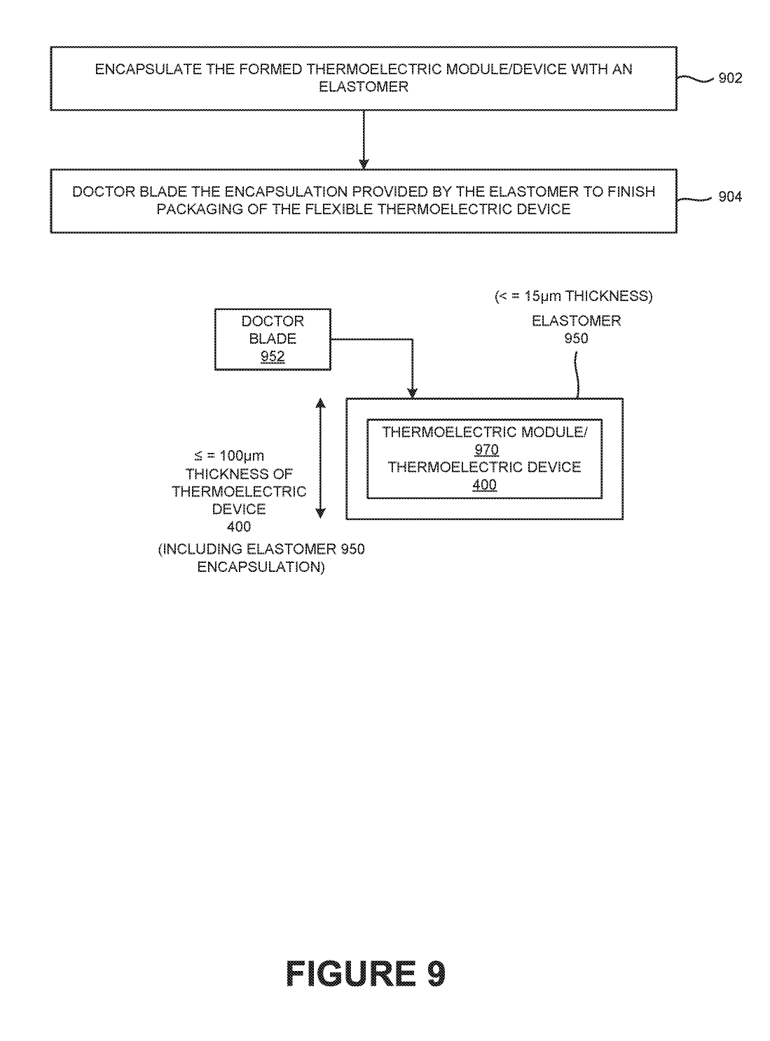

FIG. 9 details the operations involved in encapsulating the thermoelectric device (e.g., thermoelectric module 970)/module discussed above, according to one or more embodiments. In one or more embodiments, operation 902 may involve encapsulating the formed thermoelectric module (e.g., thermoelectric module 970)/device (with barrier layer 672 and conductive interconnects 696) with an elastomer 950 to render flexibility thereto. In one or more embodiments, as shown in FIG. 9, the encapsulation provided by elastomer 950 may have a dimensional thickness of less than or equal to 15 μm. In one or more embodiments, operation 904 may involve doctor blading (e.g., using doctor blade 952) the encapsulation provided by elastomer 950 to finish packaging of the flexible thermoelectric device/module discussed above.

In one or more embodiments, the doctor blading may involve controlling precision of a thickness of the encapsulation provided by elastomer 950 through doctor blade 952. In one example embodiment, elastomer 950 may be silicone. Here, said silicone may be loaded with nano-size aluminum oxide (Al₂O₃) powder to enhance thermal conductivity thereof to aid heat transfer across the thermoelectric module.

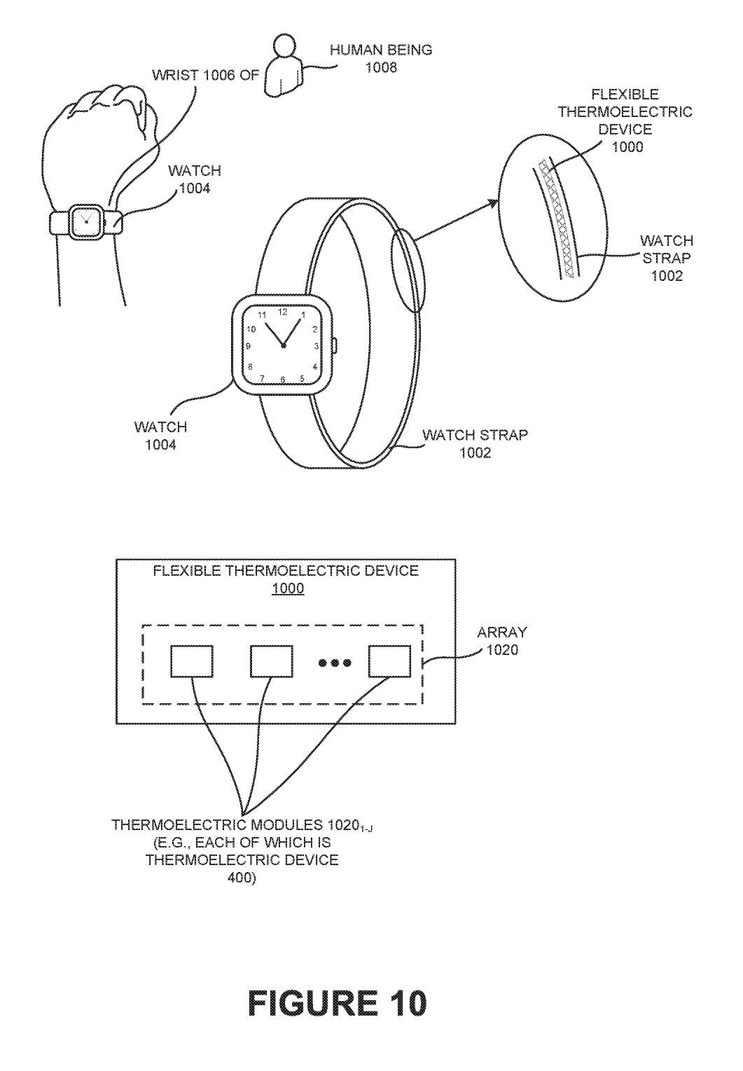

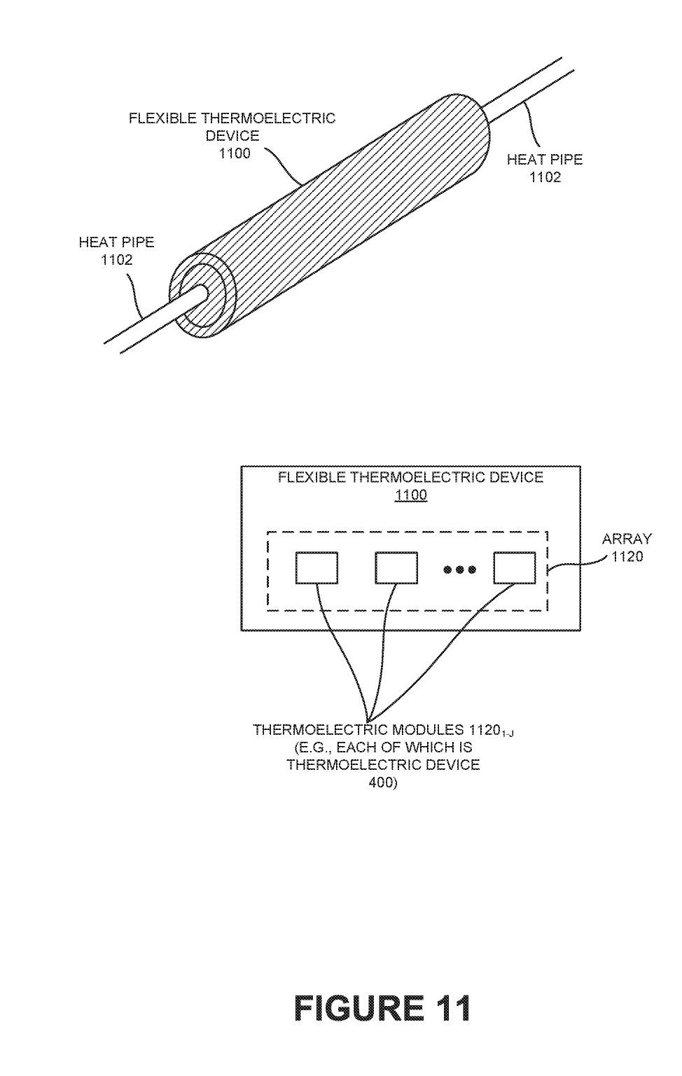

In one or more embodiments, as seen above, all operations involved in fabricating the thermoelectric device/module (e.g., thermoelectric device 400) render said thermoelectric device/module flexible. FIG. 10 shows a flexible thermoelectric device 1000 discussed herein embedded within a watch strap 1002 of a watch 1004 completely wrappable around a wrist 1006 of a human being 1008; flexible thermoelectric device 1000 may include an array 1020 of thermoelectric modules 1020_{1-J} (e.g., each of which is thermoelectric device 400) discussed herein. In one example embodiment, flexible thermoelectric device 1000 may serve to augment or substitute power derivation from a battery of watch 1004. FIG. 11 shows a flexible thermoelectric device 1100 discussed herein wrapped around a heat pipe 1102; again, flexible thermoelectric device 1100 may include an array 1120 of thermoelectric modules 1120_{1-J} (e.g., each of which is thermoelectric device 400) discussed herein. In one example embodiment, flexible thermoelectric device 1100 may be employed to derive thermoelectric power (e.g., through array 1120) from waste heat from heat pipe 1102.

It should be noted that although photomask 650 is discussed above with regard to deposition of N-type thermoelectric legs 602_{1-P} and a P-type thermoelectric legs 604_{1-P}, the aforementioned deposition may, in one or more other embodiments, involve a hard mask 690, as shown in FIG. 6. Further, it should be noted that flexible thermoelectric device 400/1000/1100 may be fabricated/manufactured such that the aforementioned device is completely wrappable and bendable around a system element (e.g., watch 1004, heat pipe 1102) that requires said flexible thermoelectric device 400/1000/1100 to perform a thermoelectric power generation function using the system element.

The abovementioned flexibility of thermoelectric device 400/1000/1100 may be enabled through proper selection of flexible substrates (e.g., substrate 350) and manufacturing techniques/processes that aid therein, as discussed above. Further, flexible thermoelectric device 1000/1100 may be bendable 360° such that the entire device may completely wrap around the system element discussed above. Still further, in one or more embodiments, an entire dimensional thickness of the flexible thermoelectric module (e.g., flexible thermoelectric device 400) in a packaged form may be less than or equal to 100 μm, as shown in FIG. 9.

Last but not the least, as the dimensions involved herein are restricted to less than or equal to 100 μm, the flexible thermoelectric device/module discussed above may be regarded as being thin-film based (e.g., including processes involved in fabrication thereof).

As seen above, examples of substrate 350 may include but are not limited to Al foil, a sheet of paper, teflon, plastic, a single-sided Cu clad laminate sheet, and a double-sided Cu clad laminate sheet. Although substrate 350 is discussed above as being less than or equal to 25 μm in dimensional thickness, concepts to be discussed below are extensible to higher values thereof. In preferred implementations, a flexible metal clad substrate 350 (e.g., Cu-clad polyimide/dielectric film) may typically be less than or equal to 100 μm (˜4 mil) in dimensional thickness; the metal (e.g., Cu) cladding on both surfaces of substrate 350 may add a small amount to the dimensional thickness. In most preferred implementations, however, the total thickness of flexible metal clad substrate 350 including the metal cladding on both surfaces may typically be less than or equal to 100 μm (˜4 mil).

Exemplary embodiments to be discussed below deal with substrate 350 being double-sided metal (e.g., Cu) clad dielectric, implying that a dielectric portion of substrate 350 is metal clad on both sides. As double-sided metal clad dielectric substrates (e.g., substrate 350) are industry-understood, detailed explanation thereof has been skipped for the sake of convenience and clarity. A preferred example of a flexible double-sided metal clad dielectric substrate may be a double-sided metal clad laminate (e.g., in the form of a sheet).

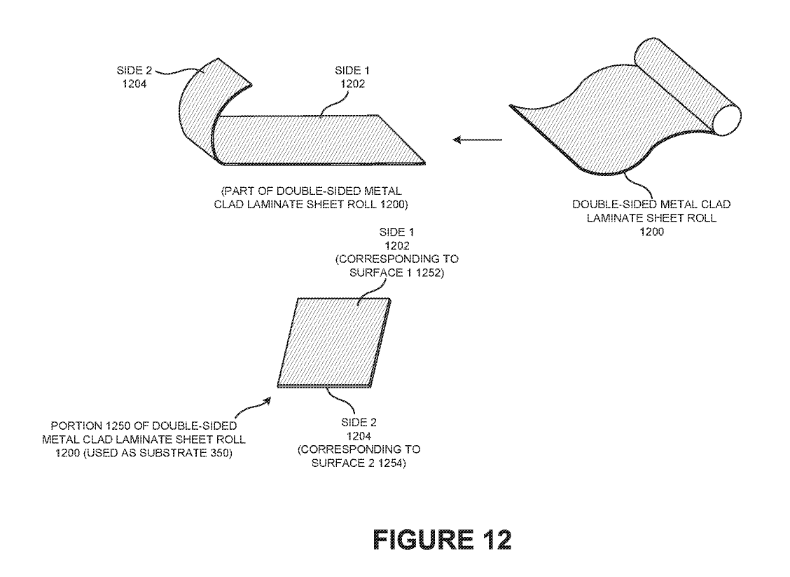

Because a double-sided metal clad dielectric substrate 350 provides two surfaces of metal cladding thereon, in one or more embodiments, the possibility of depositing thermoelectric legs (e.g., sets 302_{1-M} including N legs 304_{1-M} and P legs 306_{1-M} therein of FIG. 3, N-type thermoelectric legs 602_{1-P} and P-type thermoelectric legs 604_{1-P} of FIG. 6) on both surfaces of substrate 350 may be entertained. FIG. 12 shows a double-sided metal clad laminate sheet roll 1200, according to one or more embodiments. FIG. 12 shows side 1 1202 and side 2 1204 of double-sided metal clad laminate sheet roll, where side 1 1202 and side 2 1204 are metal cladding. While side 1 1202 and side 2 1204 may represent the same metal cladding material in preferred embodiments, concepts discussed herein can be extended to scenarios where side 1 1202 represents a first metallic material cladding and side 2 1204 represents a different second metallic material cladding.

FIG. 12 also shows a portion 1250 (e.g., cut in an appropriate shape (e.g., square)) of double-sided metal clad laminate sheet roll 1200 to be used as substrate 350. Obviously, one can regard the top surface of portion 1250 to be side 1 1202 (or, surface 1 1252; surface 1 1252 may obviously be patterned to form the electrically conductive pads 506_{1-N}, electrically conductive leads 512_{1-P} and so on) and the bottom surface of portion 1250 to be side 2 1204 (or, surface 2 1254; again, surface 2 1254 may be patterned analogous to surface 1 1254) for the sake of convenience.

It is easy to envision thermoelectric device component 300 of FIG. 3 as including sets 302_{1-M} of N legs 304_{1-M} and P legs 306_{1-M} (and terminals 370 and 372) deposited on top of surface 1 1252. It is also easy to envision portion 1250 flipped over and the same sets 302_{1-M} of N legs 304_{1-M} and P legs 306_{1-M} (and terminals 370 and 372) being deposited on surface 2 1254. For the sake of avoiding redundancy, FIG. 3 has not been reproduced here. The same discussion involving deposition of N-type thermoelectric legs 602_{1-P} and P-type thermoelectric legs 604_{1-P} (and other associated components) on top of surface 1 1252 and surface 2 1254 is applicable to FIG. 6.

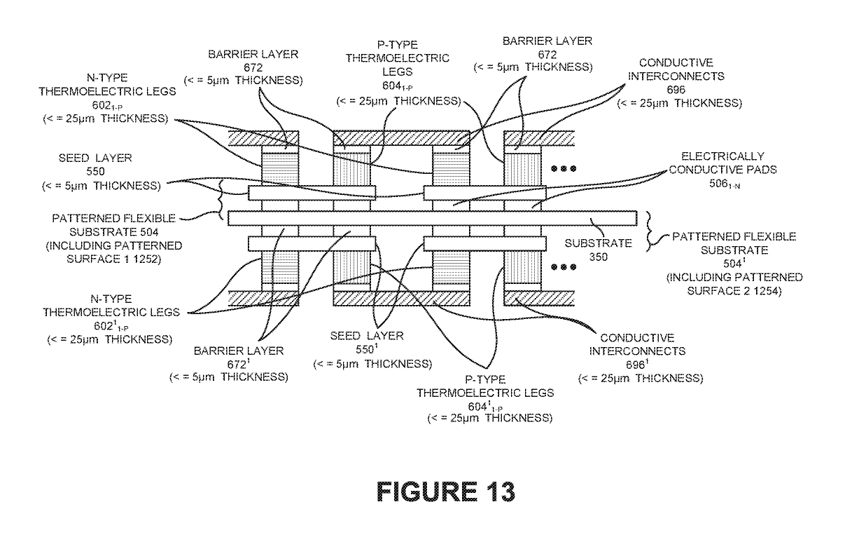

FIG. 13 shows a patterned flexible substrate 504¹ analogous to patterned flexible substrate 504 of FIGS. 4-5, both of which cover patterned forms of surface 2 1254 and surface 1 1252 respectively, according to one or more embodiments. In one or more embodiments, on each of surface 1 1252 and surface 2 1254, N-type thermoelectric legs 602_{1-P}, P-type thermoelectric legs 604_{1-P}, barrier layer 672 and conductive interconnects 696 may be deposited. Components on surface 2 1254 exactly corresponding to those on surface 1 1252 are marked with a superscript for purposes of easy differentiation. The aforementioned components on surface 2 1254 are marked in FIG. 13 as patterned flexible substrate 504¹, electrically conductive pads 506¹_{1-N}, electrically conductive leads 512¹_{1-P}, seed layer 550¹, N-type thermoelectric legs 602¹_{1-P}, P-type thermoelectric legs 604¹_{11-P}, barrier layer 672¹ and conductive interconnects 696¹. It is obvious that the formation of the aforementioned components on surface 2 1254 involve the same processes discussed above with reference to the un-superscripted components on surface 1 1252 and those of FIGS. 1-11; functionalities thereof are also similar to the un-superscripted components on surface 1 1252 and those of FIGS. 1-11.

It is to be noted that the thicknesses in FIG. 13 are merely for indicative purposes. Thickness values outside the values indicated therein are within the scope of the exemplary embodiments discussed herein.

Thus, in one or more embodiments, the utilization of both surface 1 1252 and surface 2 1254 in a thermoelectric device (e.g., thermoelectric device 400, flexible thermoelectric device 1000/1100) may approximately double performance by enabling two thermoelectric device components (e.g., two of thermoelectric device component 300) utilize a given temperature difference between surface 1 1252 and surface 2 1254 instead of merely one. The efficiency in utilization of the given temperature difference may lead to the aforementioned improved performance. As two sets of thermoelectric legs (one on top of surface 1 1252 and one on top of surface 2 1254; each thermoelectric leg is equal in length across sets for illustrative purposes) in a thermoelectric device (e.g., thermoelectric device 400, flexible thermoelectric device 1000/1100) provide for double the effective thermoelectric thickness compared to merely one set therein, the performance of the abovementioned thermoelectric device may approximately be doubled for a given temperature difference between both the metal clad surfaces (e.g., patterned surface 1 1252 and patterned surface 2 1254). All reasonable variations are within the scope of the exemplary embodiments discussed herein.

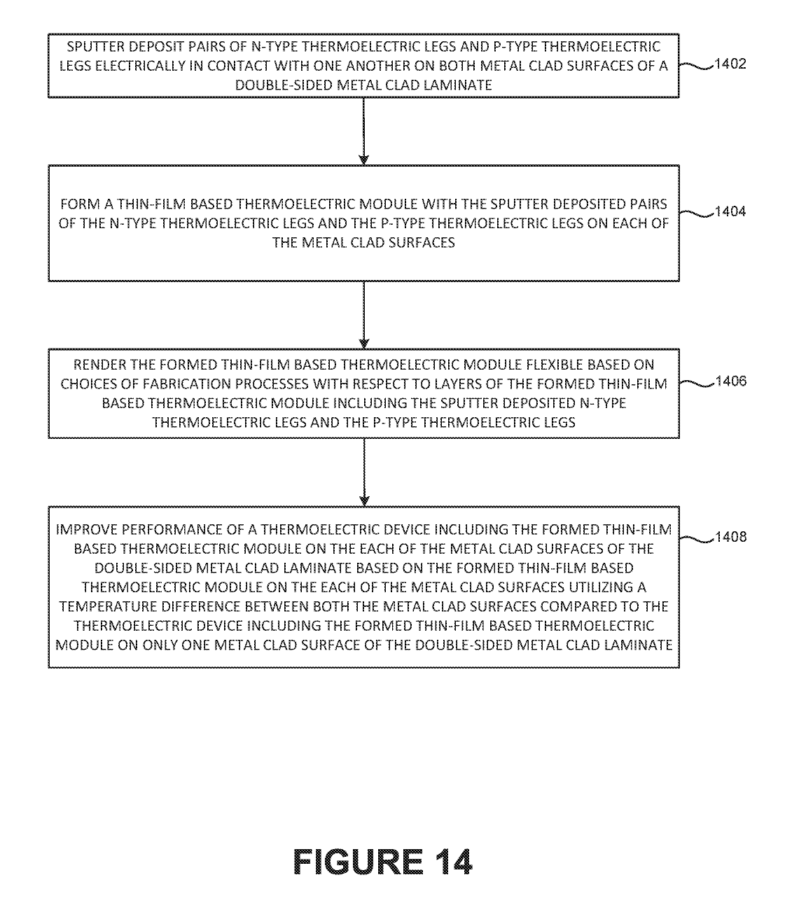

FIG. 14 shows a process flow diagram detailing the operations involved in improving performance of a thermoelectric device (e.g., thermoelectric device 400), according to one or more embodiments. In one or more embodiments, operation 1402 may involve sputter depositing pairs of N-type thermoelectric legs (e.g., N-type thermoelectric legs 602_{1-P}) and P-type thermoelectric legs (e.g., P-type thermoelectric legs 604_{1-P}) electrically in contact with one another on both metal clad surfaces (e.g., surface 1 1252 and surface 2 1254) of a double-sided metal clad laminate (example substrate 350 (e.g., portion 1250)). In one or more embodiments, the double-sided metal clad laminate may serve as a flexible substrate.

In one or more embodiments, operation 1404 may involve forming a thin-film based thermoelectric module (e.g., thermoelectric module 970) with the sputter deposited pairs of the N-type thermoelectric legs and the P-type thermoelectric legs on each of the metal clad surfaces.

In one or more embodiments, operation 1406 may involve rendering the formed thin-film based thermoelectric module flexible based on choices of fabrication processes with respect to layers of the formed thin-film based thermoelectric module including the sputter deposited N-type thermoelectric legs and the P-type thermoelectric legs. In one or more embodiments, the flexibility may enable an array (e.g., array 1020/1120) of thin-film based thermoelectric modules, each of which is equivalent to the thin-film based thermoelectric module formed on the each of the metal clad surfaces, to be completely wrappable and bendable around a system element (e.g., watch 1004, heat pipe 1102) from which the array of the thin-film based thermoelectric modules is configured to derive thermoelectric power.

In one or more embodiments, operation 1408 may then involve improving performance of the thermoelectric device including the formed thin-film based thermoelectric module on the each of the metal clad surfaces of the double-sided metal clad laminate based on the formed thin-film based thermoelectric module on the each of the metal clad surfaces utilizing a temperature difference between both the metal clad surfaces compared to the thermoelectric device including the formed thin-film based thermoelectric module on only one metal clad surface of the double-sided metal clad laminate.

Although the present embodiments have been described with reference to specific example embodiments, it will be evident that various modifications and changes may be made to these embodiments without departing from the broader spirit and scope of the various embodiments. Accordingly, the specification and drawings are to be regarded in an illustrative rather than a restrictive sense.

What is claimed is:

1. A method comprising:
sputter depositing pairs of N-type thermoelectric legs and P-type thermoelectric legs electrically in contact with one another on both metal clad surfaces of a double-sided metal clad laminate, the double-sided metal clad laminate serving as a flexible substrate;
forming a thin-film based thermoelectric module with the sputter deposited pairs of the N-type thermoelectric legs and the P-type thermoelectric legs on each of the metal clad surfaces;
rendering the formed thin-film based thermoelectric module flexible based on choices of fabrication processes with respect to layers of the formed thin-film based thermoelectric module including the sputter deposited N-type thermoelectric legs and the P-type thermoelectric legs, the flexibility enabling an array of thin-film based thermoelectric modules, each of which is equivalent to the thin-film based thermoelectric module formed on the each of the metal clad surfaces, to be completely wrappable and bendable around a system element from which the array of the thin-film based thermoelectric modules is configured to derive thermoelectric power; and
improving performance of a thermoelectric device comprising the formed thin-film based thermoelectric module on the each of the metal clad surfaces of the double-sided metal clad laminate based on the formed thin-film based thermoelectric module on the each of the metal clad surfaces utilizing a temperature difference between both the metal clad surfaces compared to the thermoelectric device comprising the formed thin-film based thermoelectric module on only one metal clad surface of the double-sided metal clad laminate.

2. The method of claim 1, comprising utilizing one of: a photomask and a hard mask with patterns corresponding to one of: the N-type thermoelectric legs and the P-type thermoelectric legs to aid the sputter deposition thereof.

3. The method of claim 1, further comprising:
printing and etching a design pattern of metal onto the each of the metal clad surfaces to form electrically conductive pads, leads and terminals therewith;
additionally electrodepositing a seed metal layer comprising at least one of:
Chromium (Cr), Nickel (Ni) and Gold (Au) directly on top of the formed electrically conductive pads, the leads and the terminals following the printing and etching thereof; and
sputter depositing the N-type thermoelectric legs and the P-type thermoelectric legs directly on top of the electrodeposited seed metal layer.

4. The method of claim 3, further comprising sputter depositing a barrier metal layer comprising one of: Cr, Ni and Au on top of the sputter deposited pairs of the N-type thermoelectric legs and the P-type thermoelectric legs utilizing one of: another photomask and another hard mask to further aid metallization contact therewith.

5. The method of claim 4, further comprising depositing conductive interconnects on top of the sputter deposited barrier metal layer utilizing a hard mask to assist selective application thereof.

6. The method of claim 5, further comprising depositing the conductive interconnects through screen printing conductive forms of ink on the sputter deposited barrier metal layer.

7. The method of claim 1, further comprising encapsulating the formed thin-film based thermoelectric module with an elastomer to render the flexibility thereto.

8. The method of claim 7, comprising the elastomer being silicone, and wherein the method further comprises:
loading the silicone with nano-size aluminum oxide (Al₂O₃) powder to enhance thermal conductivity thereof to aid heat transfer across the formed thin-film based thermoelectric module.

9. A method comprising:
sputter depositing pairs of N-type thermoelectric legs and P-type thermoelectric legs electrically in contact with one another on both metal clad surfaces of a double-sided metal clad laminate, the double-sided metal clad laminate serving as a flexible substrate;
forming a thin-film based thermoelectric module with the sputter deposited pairs of the N-type thermoelectric legs and the P-type thermoelectric legs on each of the metal clad surfaces;
rendering the formed thin-film based thermoelectric module flexible based on choices of fabrication processes with respect to layers of the formed thin-film based thermoelectric module including the sputter deposited N-type thermoelectric legs and the P-type thermoelectric legs;
wrapping and bending an array of thin-film based thermoelectric modules, each of which is equivalent to the thin-film based thermoelectric module formed on the each of the metal clad surfaces, completely around a system element from which the array of the thin-film based thermoelectric modules is configured to derive thermoelectric power in accordance with the flexibility thereof; and
improving performance of a thermoelectric device comprising the formed thin-film based thermoelectric module on the each of the metal clad surfaces of the double-sided metal clad laminate based on the formed thin-film based thermoelectric module on the each of the metal clad surfaces utilizing a temperature difference between both the metal clad surfaces compared to the thermoelectric device comprising the formed thin-film based thermoelectric module on only one metal clad surface of the double-sided metal clad laminate.

10. The method of claim 9, comprising utilizing one of: a photomask and a hard mask with patterns corresponding to one of: the N-type thermoelectric legs and the P-type thermoelectric legs to aid the sputter deposition thereof.

11. The method of claim 9, further comprising:
printing and etching a design pattern of metal onto the each of the metal clad surfaces to form electrically conductive pads, leads and terminals therewith;
additionally electrodepositing a seed metal layer comprising at least one of: Cr, Ni and Au directly on top of the formed electrically conductive pads, the leads and the terminals following the printing and etching thereof; and
sputter depositing the N-type thermoelectric legs and the P-type thermoelectric legs directly on top of the electrodeposited seed metal layer.

12. The method of claim 11, further comprising sputter depositing a barrier metal layer comprising one of: Cr, Ni and Au on top of the sputter deposited pairs of the N-type thermoelectric legs and the P-type thermoelectric legs utilizing one of: another photomask and another hard mask to further aid metallization contact therewith.

13. The method of claim 12, further comprising depositing conductive interconnects on top of the sputter deposited barrier metal layer utilizing a hard mask to assist selective application thereof.

14. The method of claim 13, further comprising depositing the conductive interconnects through screen printing conductive forms of ink on the sputter deposited barrier metal layer.

15. The method of claim 9, further comprising encapsulating the formed thin-film based thermoelectric module with an elastomer to render the flexibility thereto.

16. A method comprising:
sputter depositing pairs of N-type thermoelectric legs and P-type thermoelectric legs electrically in contact with one another on both metal clad surfaces of a double-sided metal clad laminate, the double-sided metal clad laminate serving as a flexible substrate;
forming a thin-film based thermoelectric device out of an array of thermoelectric modules, each of which is formed with the sputter deposited pairs of the N-type thermoelectric legs and the P-type thermoelectric legs on each of the metal clad surfaces;
rendering the formed thin-film based thermoelectric device flexible based on choices of fabrication processes with respect to layers of the each thermoelectric module including the sputter deposited N-type thermoelectric legs and the P-type thermoelectric legs, the flexibility enabling the formed thin-film based thermoelectric device to be completely wrappable and bendable around a system element from which the formed thin-film based thermoelectric device is configured to derive thermoelectric power; and
improving performance of the formed thin-film based thermoelectric device based on the each thermoelectric module of the array of thermoelectric modules with the sputter deposited pairs of the N-type thermoelectric legs and the P-type thermoelectric legs on the each of the metal clad surfaces utilizing a temperature difference between both the metal clad surfaces compared to the each thermoelectric module with the sputter deposited pairs of the N-type thermoelectric legs and the P-type thermoelectric legs on only one metal clad surface of the double-sided metal clad laminate thereof.

17. The method of claim 16, comprising utilizing one of: a photomask and a hard mask with patterns corresponding to one of: the N-type thermoelectric legs and the P-type thermoelectric legs to aid the sputter deposition thereof.

18. The method of claim 16, further comprising:
printing and etching a design pattern of metal onto the each of the metal clad surfaces to form electrically conductive pads, leads and terminals therewith;
additionally electrodepositing a seed metal layer comprising at least one of: Cr, Ni and Au directly on top of the formed electrically conductive pads, the leads and the terminals following the printing and etching thereof; and
sputter depositing the N-type thermoelectric legs and the P-type thermoelectric legs directly on top of the electrodeposited seed metal layer.

19. The method of claim 18, further comprising sputter depositing a barrier metal layer comprising one of: Cr, Ni and Au on top of the sputter deposited pairs of the N-type thermoelectric legs and the P-type thermoelectric legs utilizing one of: another photomask and another hard mask to further aid metallization contact therewith.

20. The method of claim 19, further comprising at least one of:
depositing conductive interconnects on top of the sputter deposited barrier metal layer utilizing a hard mask to assist selective application thereof; and
encapsulating the each thermoelectric module with an elastomer to render the flexibility thereto.
